(19) United States
(12) Patent Application Publication
(10) Pub. No.: US 2010/0326524 A1
(43) Pub. Date: Dec. 30, 2010

(54) ORGANIC SOLAR CELL AND METHOD OF FABRICATING THE SAME

(75) Inventors: Soo-Ghang IHN, Hwaseong-si (KR); Woong CHOI, Seongnam-si (KR); Jae-Young CHOI, Suwon-si (KR)

Correspondence Address: CANTOR COLBURN LLP, 20 Church Street, 22nd Floor, Hartford, CT, 06103, US

(73) Assignee: SAMSUNG ELECTRONICS CO., LTD., Suwon-si (KR)

(21) Appl. No.: 12/697,654

(22) Filed: Feb. 1, 2010

(30) Foreign Application Priority Data
Jun. 30, 2009 (KR) 10-2009-0059273
Oct. 13, 2009 (KR) 10-2009-0097444

(51) Int. Cl. H01L 31/00; H01L 31/18

(52) U.S. Cl. 136/261; 438/57

(57) ABSTRACT

An organic solar cell includes; a cathode, an anode disposed substantially opposite the cathode, a photoactive layer disposed between the cathode and the anode, and an electron blocking layer disposed between the anode and the photoactive layer, wherein the photoactive layer includes; an electron donor, an electron acceptor disposed adjacent to the electron donor, and a nanostructure disposed adjacent to at least one of the electron donor and the electron acceptor, wherein the nanostructure is connected to the anode, and includes a hole transporting material selected from the group consisting of a semiconductor element, a semiconductor compound, a semiconductor carbon material, and a combination thereof, and the semiconductor element, the semiconductor compound, or the semiconductor carbon material satisfies the following Equation 1 and 2:

|LUMO_{A}|>|CBE_{N}| [Equation 1]

|HOMO_{D}|>|VBE_{N}| [Equation 2]
wherein in Equation 1 and 2, LUMO_{A}, CBE_{N}, HOMO_{D}, and VBE_{N} are the same as in the detailed description.

### CROSS-REFERENCE TO RELATED APPLICATION

This application claims priority to Korean Patent Application No. 10-2009-0059273, filed on Jun. 30, 2009 and Korean Patent Application No. 10-2009-0097444, filed on Oct. 13, 2009, and all the benefits accruing therefrom under 35 U.S.C. §119, the contents of which in their entirety are herein incorporated by reference.

### BACKGROUND

1. Field

This disclosure relates to an organic solar cell and a method of fabricating the same.

2. Description of the Related Art

A solar cell is a photoelectric conversion device that transforms solar energy, or photonic energy from other sources, into electrical energy, and has garnered much attention as an infinite, i.e., renewable, pollution-free next generation energy resource.

In general, a solar cell may be classified as an inorganic solar cell or an organic solar cell depending on a material forming a thin film thereof. Since the organic solar cell includes various organic semiconductor materials in a small amount, it may have a decreased cost as compared to the inorganic type of solar cell. In addition, since the various organic semiconductor materials are made into a thin film fabricated in a solution-based process, the organic solar cell device may be fabricated using a simple method.

In general, an organic solar cell is classified as a bi-layer p-n junction organic solar cell including a photoactive layer including two layers such as a p-type semiconductor thin film and an n-type semiconductor thin film, or a bulk hetero-junction (“BHJ”) organic solar cell including a photoactive layer including an n-type semiconductor and a p-type semiconductor blended together, depending on the desired structure of the photoactive layer.

An example of the bi-layer p-n junction-type organic solar cell is shown in FIG. 4. Referring to FIG. 4, an organic solar cell 100 includes a substrate 101, an indium tin oxide (“ITO”) anode 103, a photoactive layer 111, and a cathode 105. The photoactive layer 111 includes a p-type semiconductor thin film 107 and an n-type semiconductor thin film 109. Herein, excitons 117 including pairs of electrons 113 and holes 115 are formed within the p-type semiconductor thin film 107, when excited. The excitons 117 are separated into individual charge carriers, e.g., electrons 113 and individual holes 115, at a p-n junction part wherein the p-type semiconductor thin film 107 and the n-type semiconductor thin film 109 meet. The separated electrons 113 and holes 115 respectively move to the n-type semiconductor thin film 109 and the p-type semiconductor thin film 107, and are respectively accepted to the cathode 105 and the anode 103 such that they may be externally used as electrical energy, e.g., they may generate an electrical current.

It is desirable for a solar cell to have a high degree of efficiency to produce as much electrical energy from the light source to which it is exposed, e.g., the sun, as possible. In order to increase the efficiency of a solar cell, as many excitons as possible are produced, and a resultant charge is withdrawn with minimal loss of charge carriers before they are absorbed into the respective electrodes 103 and 105.

A significant amount of the lost charge is due to recombination of the produced electrons 113 and holes 115 before the charge carriers can be absorbed at the electrodes 103 and 105. Accordingly, various methods of transferring the produced electrons 113 and holes 115 to an electrode with minimal loss have been suggested. However, they generally require an additional process and thereby increase the manufacturing cost of the associated solar cell.

### SUMMARY

One aspect of this disclosure provides an embodiment of an organic solar cell having increased an amount of photocurrent and improved photoelectric conversion efficiency by improving a path for the movement of holes in a photoactive layer.

Another aspect of this disclosure provides a method of fabricating an organic solar cell with high efficiency by a simple method and with a low cost.

According to one, aspect of this disclosure, an embodiment of an organic solar cell includes; a cathode, an anode disposed substantially opposite the cathode, a photoactive layer disposed between the cathode and the anode, and an electron blocking layer disposed between the anode and the photoactive layer, wherein the photoactive layer includes an electron donor, an electron acceptor disposed adjacent to the electron donor, and a nanostructure disposed adjacent to at least one of the electron donor and the electron acceptor, wherein the nanostructure is connected to the anode and includes a hole transporting material selected from the group consisting of a semiconductor element, a semiconductor compound, a semiconductor carbon material, and a combination thereof, and wherein the semiconductor element, the semiconductor compound, or the semiconductor carbon material satisfies the following Equation 1 and Equation 2:

|LUMO_{A}|>|CBE_{N}| [Equation 1]

|HOMO_{D}|>|VBE_{N}| [Equation 2]

wherein in Equation 1, LUMO_{A} refers to an energy level of a lowest unoccupied molecular orbital (“LUMO”) of the electron acceptor and CBE_{N} refers to a conduction band edge (“CBE”) of the nanostructure, while in Equation 2, HOMO_{D} refers to an energy level of a highest occupied molecular orbital (“HOMO”) of the electron donor and VBE_{N} refers to a valance band edge (“VBE”) of the nanostructure.

In one embodiment, the semiconductor element may include silicon (Si), germanium (Ge) or a combination thereof.

In one embodiment, the semiconductor compound may include a group II-VI compound, a group III-V compound, a group IV-VI compound, a group IV compound, a semiconductor metal oxide, or a combination thereof.

In one embodiment, the semiconductor carbon material may include one selected from the group consisting of carbon nanotube, graphene, and a combination thereof.

In one embodiment, the nanostructure may have a substantially one-dimensional linear structure, a substantially two-dimensional flat structure, or a three-dimensional cubic structure. In one embodiment, the nanostructure may include one selected from the group consisting of nanotubes, nanorods, nanowires, nanotrees, nanotetrapods, nanodisks, nanoplates, nanoribbons and a combination thereof.

In one embodiment, the nanostructure may be treated to have a surface roughness or hydrophilic surface.

In one embodiment, the nanostructure may be included in an amount of about 0.1% to about 50% of the entire volume of the photoactive layer.

In one embodiment, a hole blocking layer may be disposed between the cathode and the photoactive layer.

According to another aspect, an embodiment of an organic solar cell includes; a cathode, an anode disposed substantially opposite the cathode, a photoactive layer disposed between the cathode and the anode, and an electron blocking layer disposed between the anode and the photoactive layer, wherein the photoactive layer includes an electron donor, an electron acceptor disposed adjacent to the electron donor, and a nanostructure disposed adjacent to at least one of the electron donor and the electron acceptor,

wherein some of the nanostructure is connected to the anode, and includes a hole transporting material selected from the group consisting of a semiconductor element, a semiconductor compound, a semiconductor carbon material, and a combination thereof, and wherein the semiconductor element, the semiconductor compound, or the semiconductor carbon material, which are included in the nanostructure connected to the anode, satisfy the above Equation 1 and Equation 2, and

wherein the rest of the nanostructure is connected to the cathode, and includes an electron conductive material selected from the group consisting of a semiconductor element, a semiconductor compound, a semiconductor carbon material, a metallic carbon material which is surface-treated with a hole blocking material, a metal which is surface-treated with a hole blocking material and a combination thereof.

According to another aspect, an embodiment of a method of fabricating an organic solar cell is provided, which includes; providing an anode on a substrate, providing a nanostructure on the anode such that the nanostructure is arranged in a direction substantially perpendicular to the anode, and at the same time providing an electron blocking layer on the anode, coating a mixed solution of an electron donor and an electron acceptor on the nanostructure to form a photoactive layer, and providing a cathode on the photoactive layer, wherein the nanostructure is formed to have characteristics similar to those described above.

In one embodiment, a hole blocking layer may be further disposed between the cathode and the photoactive layer.

In one embodiment, the nanostructure may be pretreated by at least one selected from the group consisting of forming a surface roughness by selective etching and making the surface hydrophilic.

According to another aspect, an embodiment of a method of fabricating an organic solar cell is provided, which includes; providing an anode on a substrate, providing an electron blocking layer on the anode, providing a nanostructure on the electron blocking layer such that the nanostructure is arranged in a direction substantially perpendicular to the electron blocking layer, coating a mixed solution of an electron donor and an electron acceptor on the nanostructure to form a photoactive layer, and providing a cathode on the photoactive layer, wherein the nanostructure is formed to have characteristics similar to those described above.

Other aspects of this disclosure will be described in the following detailed description.

### BRIEF DESCRIPTION OF THE DRAWINGS

The above and other aspects, advantages and features of this disclosure will become more apparent by describing in further detail exemplary embodiments thereof with reference to the accompanying drawings, in which:

FIG. 1 is a cross-sectional view of an embodiment of an organic solar cell;

FIG. 2 is a cross-sectional view of another embodiment of an organic solar cell;

FIG. 3 is a cross-sectional view of another embodiment of an organic solar cell;

FIG. 4 is a cross-sectional view of another embodiment of an organic solar cell;

FIG. 5 is a cross-sectional view of another embodiment of an organic solar cell;

FIG. 6 is a cross-sectional view of another embodiment of an organic solar cell;

FIG. 7 is a flow chart showing an embodiment of a fabricating process of an organic solar cell;

FIG. 8 is a flow chart showing another embodiment of a fabricating process of an organic solar cell; and

FIG. 9 schematically shows a structure of a bi-layer p-n junction organic solar cell of the prior art.

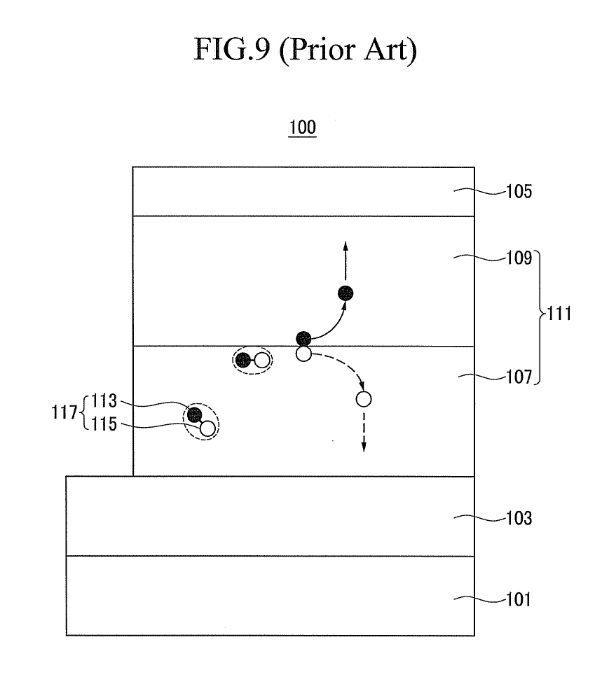

### DETAILED DESCRIPTION

This disclosure will now be described more fully hereinafter with reference to the accompanying drawings, in which embodiments of the disclosure are shown. This disclosure may, however, be embodied in many different forms and should not be construed as limited to the embodiments set forth herein. Rather, these embodiments are provided so that this disclosure will be thorough and complete, and will fully convey the scope thereof to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

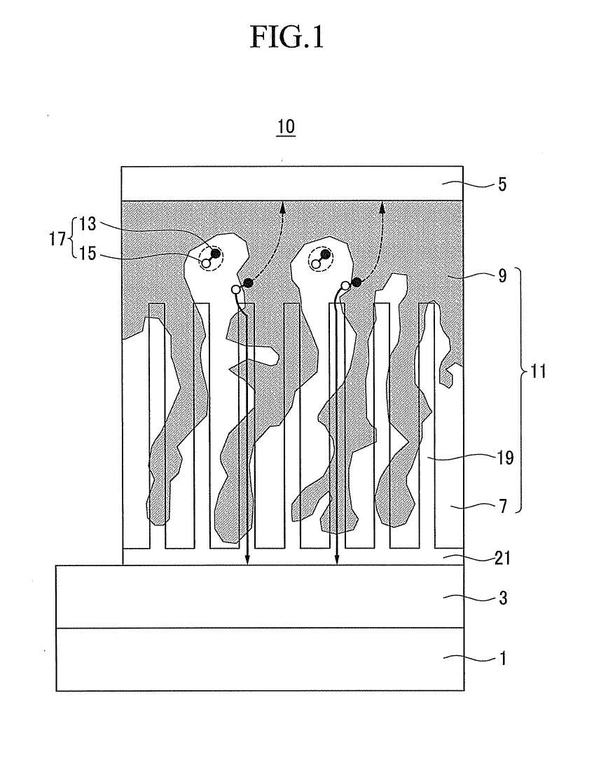

Hereinafter, referring to FIGS. 1 to 6, embodiments of organic solar cells are described.

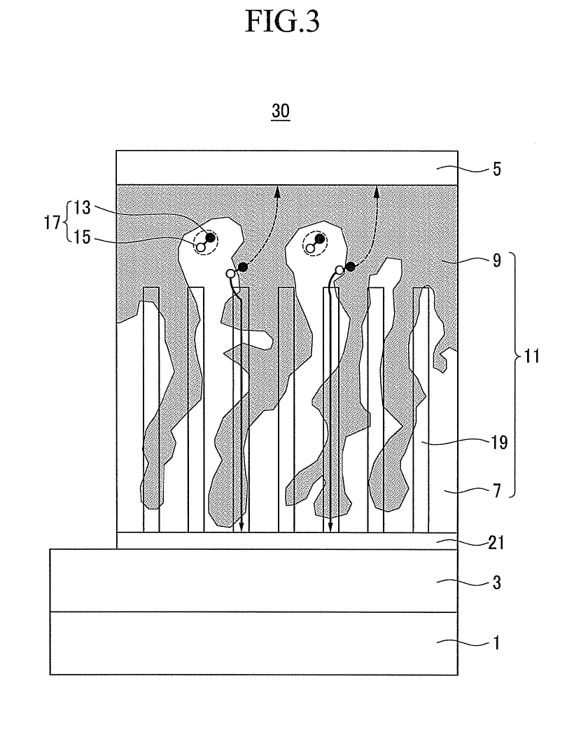

FIGS. 1 and 3 are cross-sectional views of embodiments of organic solar cells 10 and 30. The organic solar cells 10 and 30 include a photoactive layer 11 between a cathode 5 and an anode 3 positioned on a substrate 1, and an electron blocking layer 21 positioned between the anode 3 and the photoactive layer 11. FIGS. 1 and 3 show that the anode 3 is positioned on the substrate 1 in the organic solar cells 10 and 30, but alternative embodiments include configurations wherein the cathode 5 may be positioned on the substrate 1.

The substrate 1 may be made of a transparent material, embodiments of which include glass, polycarbonate, polymethyl methacrylate, polyethylene terephthalate, polyimide, polyethersulfone (“PES”), and other materials with similar characteristics, without particular limitation.

Embodiments of the anode 3 may include indium tin oxide (“ITO”), SnO₂, In₂O₃—ZnO, also referred to as indium zinc oxide (“IZO”), aluminum-doped ZnO (“AZO”), gallium-doped ZnO (“GZO”), and other materials with similar characteristics as a light-transmissible transparent electrode.

Materials for forming the cathode 5 may be used without any particular limitation as long as the material used has a smaller work function than that of the anode 3. Embodiments of the material for forming the cathode 5 may include a metal, a metal alloy, a semi-metal, a light-transmissible transparent oxide or combinations thereof. Examples of the metal may include an alkali metal such as lithium (Li), sodium (Na), and other materials with similar characteristics; an alkaline-earth metal such as magnesium (Mg) and other materials with similar characteristics; aluminum (Al); and transition elements such as silver (Ag), molybdenum (Mo), tantalum (Ta), vanadium (V), tungsten (W), and other materials with similar characteristics. Examples of the metal alloy may include a germanium-gold alloy, an aluminum-lithium alloy, and other materials with similar characteristics. In addition, the cathode 5 may include a laminate including a first layer formed of the metal or the metal alloy and a second layer formed of the metal oxide, the metal halide, or the metal. For example, in one embodiment the cathode 5 may include an electrode such as LiF/Al, Ca/Al, TiOₓ/Al, ZnO/Al, and other materials with similar characteristics. The light-transmissible transparent oxide may include ITO, SnO₂, IZO, AZO, GZO, and the like mentioned above for the anode 3 material, and has a smaller work function than the anode 3.

The photoactive layer 11 may include an electron donor 7 and an electron acceptor 9 mixed together, and a nanostructure 19 which functions as a hole transporter.

The electron donor 7 may include a conductive polymer, a low molecular weight semiconductor, and other materials with similar characteristics as a p-type semiconductor. Examples thereof may include polyaniline, polypyrrol, polythiophene, poly(p-phenylene vinylene), poly[2-methoxy-5-(2′-ethyl-hexyloxy)-1,4-phenylene vinylene (“MEH-PPV”), poly(2-methoxy-5-(3,7-dimethyloctyloxy)-1,4-phenylene vinylene (“MDMO-PPV”), pentacene, poly(3,4-ethylenedioxythiophene) (“PEDOT”), metal phthalocyanine, for example copper phthalocyanine (CuPc), poly(3-alkylthiophene), for example, poly(3-hexylthiophene) (“P3HT”), and other materials with similar characteristics.

The electron acceptor 9 may include fullerene with a large affinity to electrons (e.g., C60, C70, C74, C76, C78, C82, C84, C720, C860, and other materials with similar characteristics); fullerene derivatives such as 1-(3-methoxy-carbonyl)propyl-1-phenyl-(6,6) C61 (“PCBM”), C71-PCBM, C84-PCBM, bis-PCBM, and other materials with similar characteristics; perylene; an inorganic semiconductor such as CdS, CdTe, CdSe, ZnO, TiOx, Si, GaAs, InP, GaP, AlAs, and other materials with similar characteristics; or a mixture thereof.

In one embodiment, the electron donor 7 and the electron acceptor 9 may be mixed in a weight ratio of about 1:9 to about 9:1. When the electron donor 7 and electron acceptor 9 are mixed within the above-specified range, a photoactive layer 11 may be easily formed for improvement of photocurrent efficiency, as will be discussed in more detail below.

Photo-excitement produces excitons 17 including an electron 13 and a hole 15 pair from both the electron donor 7 and the electron acceptor 9, respectively. The electron 13 and the hole 15 may also be referred to as charge carriers. Each exciton 17 is separated into an individual electron 13 and an individual hole 15 at the interface of the electron donor 7 and the electron acceptor 9 due to an affinity difference of the two materials. The separated electron 13 moves towards the cathode 5 through the electron acceptor 9, and the hole 15 moves towards the anode 3 through an electron donor 7 due to a built-in electric field. The hole 15 hops across lobes of the electron donor 7 when it moves towards the anode 3. However, due to this hopping process for hole transport, the hole 15 moves at a slow speed and restricts the amount of photocurrent which may be produced by the solar cell.

Therefore, the nanostructure 19 is included as a hole transporter in the photoactive layer 11. The hole 15 may move through the nanostructure 19 while it is moving towards the anode 3 in order to increase speed of movement of the hole 15 separated from the exciton 17 toward the anode 3, e.g., the movement of the hole 15 along the nanostructure 19 prevents the hopping phenomenon discussed above. As a result, the hole 15 may be recombined with the electron 13 at a lower level at the anode 3 and increase the amount of photocurrent available, thereby improving photoelectric conversion efficiency of the solar cells 10 and 30. In addition, the nanostructure 19 may scatter light, increasing the light path in the photoactive layer 11, resultantly improving photoelectric conversion efficiency by increasing the probability that a photon will interact with an exciton 17 in the photoactive layer.

As shown in FIGS. 1 and 3, the nanostructure 19 is connected to the anode 3. The hole 15 may move through the nanostructure 19 to anode 3 efficiently, and increases a hole-collecting area and hole-collecting efficiency, resultantly contributing to an increase in photoelectric conversion efficiency.

The nanostructure 19 may include one selected from the group consisting of a semiconductor element, a semiconductor compound, a semiconductor carbon material, and a combination thereof.

When the semiconductor, the semiconductor metal oxide, and the semiconductor carbon material satisfies the following Equations 1 and 2, they have excellent electron blocking and hole transporting properties.

|LUMO_{A}|>|CBE_{N}| [Equation 1]

|HOMO_{D}|>|VBE_{N}| [Equation 2]

In Equation 1, LUMO_{A} refers to an energy level of a lowest unoccupied molecular orbital (“LUMO”) of the electron acceptor 9 and CBE_{N} refers to a conduction band edge (“CBE”) of the nanostructure 19. In Equation 2, HOMO_{D} refers to an energy level of a highest occupied molecular orbital (“HOMO”) of the electron donor 7 and VBE_{N} refers to a valance band edge (“VBE”) of the nanostructure 19.

Embodiments of the semiconductor element may include silicon (Si), germanium (Ge), or a combination thereof, but the disclosure is not limited thereto.

The semiconductor compound may include a group II-VI compound, a group III-V compound, a group IV-VI compound, a group IV compound, a semiconductor metal oxide, or a combination thereof. The group II-VI compound may be selected from the group consisting of a binary element compound such as CdSe, CdS, CdTe, ZnS, ZnSe, ZnTe, ZnO, HgS, HgSe, HgTe, and other materials with similar characteristics, a ternary element compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, and other materials with similar characteristics, and a quaternary element compound such as HgZnSTe, CdZnSeS, CdZnSeTe, CdZnSTe, CdHgSeS, CdHgSeTe, CdHgSTe, HgZnSeS, HgZnSeTe, HgZnSTe, and other materials with similar characteristics; the group III-V compound may be selected from the group consisting of a binary element compound such as GaN, GaP, GaAs, GaSb, AlN, AlP, AlAs, AlSb, InN, InP, InAs, InSb, and other materials with similar characteristics, a ternary element compound such as AlGaAs, AlGaP, AlGaN, InGaAs, InGaP, InGaN, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, and other materials with similar characteristics, and a quaternary element compound such as InAlGaAs, InAlGaP, InAlGaN, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and other materials with similar characteristics; the group IV-VI compound may be selected from the group consisting of a binary element compound such as SnS, SnSe, SnTe, PbS, PbSe, PbTe, and other materials with similar characteristics, a ternary element compound such as SnSeS, SnSeTe, SnSTe, PbSeS, PbSeTe, PbSTe, SnPbS, SnPbSe, SnPbTe, and other materials with similar characteristics, and a quaternary element compound such as SnPbSSe, SnPbSeTe, SnPbSTe, and other materials with similar characteristics; the group IV compound may be selected from the group consisting of a binary element compound such as SiC, SiGe, and other materials with similar characteristics; and the semiconductive metal oxide may be selected from the group consisting of indium oxide (In₂O₃), zinc oxide (ZnO), titanium oxide, tin oxide (SnO₂), and other materials with similar characteristics.

Embodiments of the semiconductor carbon material include one selected from the group consisting of carbon nanotubes, graphene, and combinations thereof, but the disclosure is not limited thereto.

Embodiments of the nanostructure 19 may have a one-dimensional linear structure, a two-dimensional flat structure, or a three-dimensional cubic structure. As used herein, the one-dimensional linear structure indicates a structure having a thickness that may be ignored compared with the length thereof, e.g., the thickness is at least an order of magnitude smaller than the length. As used herein, the two-dimensional flat structure indicates a structure having a thickness that may be ignored compared with the area thereof, e.g., the thickness is at least an order of magnitude smaller than the area thereof. This nanostructure 19 may have various shapes such as nanotube, nanorod, nanowire, nanotree, nanotetrapod, nanodisk, nanoplate, nanoribbon, and other similar shapes. In addition, embodiments include configurations wherein different shapes of nanostructure 19 may be mixed.

As shown in FIGS. 1 and 3, a nanostructure 19 included in a photoactive layer 11 of an organic solar cells 10 and 30 may be arranged in a direction substantially perpendicular to the anode 3. Herein, the direction of the nanostructure 19 indicates that the nanostructure 19 is substantially close to 90° with respect to the anode 3, e.g., the nanostructure 19 is disposed normal to the anode 3. Therefore, in one embodiment, the nanostructure 19 may be arranged in a substantially vertical direction. When the nanostructure 19 is arranged as aforementioned, it may minimize the path for hole 15 to travel to the anode 3 and increase the amount of current available in the solar cells 10 and 30. In addition, in one embodiment, one end of the nanostructure 19 is connected to the anode 3, and thereby an area for collecting holes is increased as is collection efficiency of the holes, contributing to increasing photoelectric conversion efficiency.

As shown in FIGS. 1 and 3, the organic solar cells 10 and 30 include an electron blocking layer 21 between the anode 3 and the photoactive layer 11. As shown in FIG. 1, the electron blocking layer 21 is formed with the nanostructure 19 at the same time during forming the nanostructure 19. Meanwhile, as shown in FIG. 3, the electron blocking layer 21 is formed prior to form the nanostructure 19. Embodiments include configurations wherein the electron blocking layer 21 may be a single or multi-layer structure. Each electron blocking layer 21 may include the same material as the nanostructure 19, or may include a transition metal oxide such as MoO₃, V₂O₅, WO₃, and other materials with similar characteristics; a conductive polymer such as PEDOT:PSS, polyaniline, polypyrrole, poly(p-phenylene vinylene), MEH-PPV (poly[2-methoxy-5-(2′-ethyl-hexyloxy)-1,4-phenylene vinylene), MDMO-PPV (poly(2-methoxy-5-(3,7-dimethyloctyloxy)-1,4-phenylene vinylene), poly(3-alkylthiophene), polythiophene, and other materials with similar characteristics; pentacene; metal phthalocyanine such as copper phthalocyanine (CuPc), and other materials with similar characteristics; or a low molecular weight organic material such as triphenyldiamine derivative (“TPD”), and other materials with similar characteristics. The self-assembly monolayer (SAM) of the electron donor 7 may be formed at a place where the anode 3 does not contact with the nanostructure 19 but contacts with the photoactive layer 11. In addition, when the SAM is inserted between the anode 3 and the photoactive layer 11, it may improve hole collection efficiency and prevent recombination of electron 13 and hole 15 at the junction surface of the electron donor 7 and the anode 3.

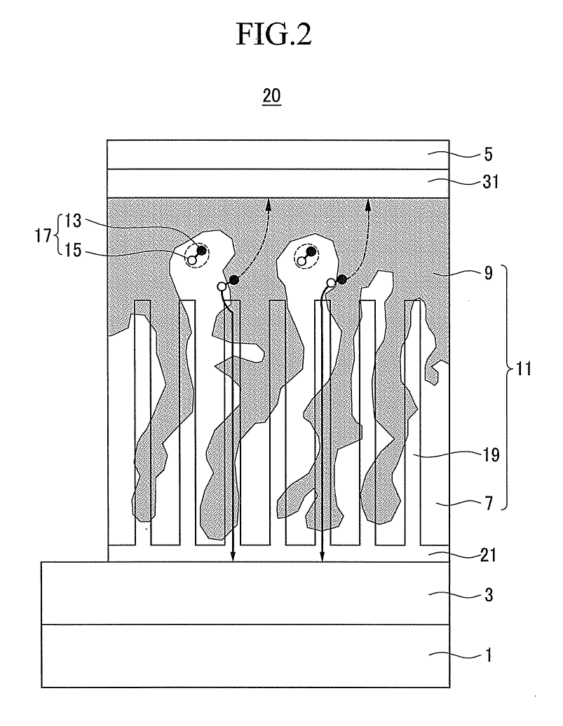

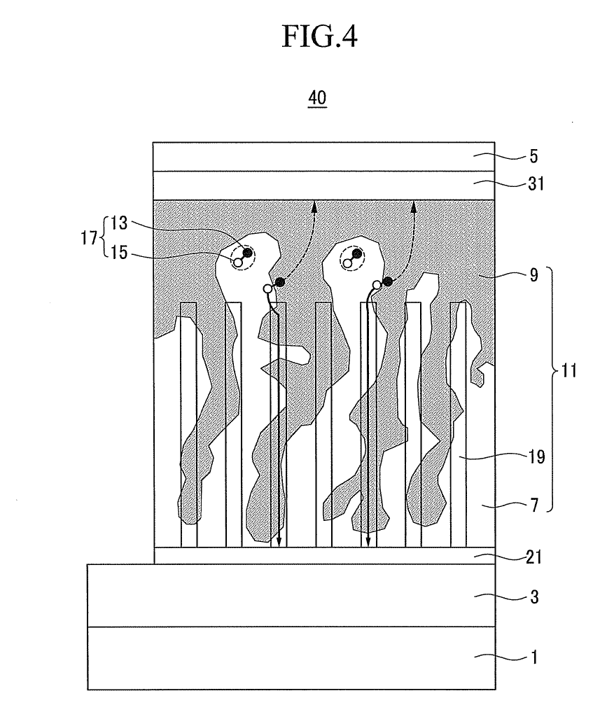

FIGS. 2 and 4 are cross-sectional views of another embodiments of organic solar cells 20 and 40. As shown in FIGS. 2 and 4, another embodiments of organic solar cells 20 and 40 further include a hole blocking layer 31 between the cathode 5 and the photoactive layer 11. The hole blocking layer 31 may prevent a short circuit that might possibly occur if the hole transport nanostructure 19 on the photoactive layer 11 were to directly contact the cathode 5. Such a hole blocking layer 31 may include fullerene (C60, C70, C74, C76, C78, C82, C84, C720, C860, and other materials with similar characteristics); fullerene derivatives such as PCBM, C71-PCBM, C84-PCBM, bis-PCBM, and other materials with similar characteristics; bathocuproine (“BCP”); a semiconductor element; a semiconductor compound; and combinations thereof. Examples of the semiconductor element and the semiconductor compound are substantially the same as an aforementioned semiconductor element and an aforementioned semiconductor compound in the nanostructure 19.

The nanostructure 19 may have a thickness ranging from about 0.8 nm to about 200 nm and a length ranging from about 100 nm to 10 μm. In addition, the nanostructure 19 may have an aspect ratio ranging from about 2 to about 2,000. The aspect ratio indicates a length/thickness ratio when the nanostructure 19 has a one-dimensional linear structure or a two-dimensional flat structure. When it has a three-dimensional cubic structure, the aspect ratio indicates a length/thickness ratio of the one-dimensional linear or two-dimensional flat structure. When the nanostructure 19 has a thickness, a length, and an aspect ratio within the above described range, it may transport and collect holes effectively, and may thereby improve photoelectric conversion efficiency of the solar cell in which it is disposed.

In addition, the nanostructure 19 may be selectively etched to have surface roughness on its surface to increase their surface area thereof and expand the contact area with the electron donor 7. Furthermore, the nanostructure 19 may be UV-treated or plasma-treated to make the surface hydrophilic.

The nanostructures 19 may be included in an amount of about 0.1% to about 50% of a volume of the entire photoactive layer 11. When the volume of the nanostructure 19 is included within the range, it may improve mobility of the produced hole 15, improving photoelectric conversion efficiency of the solar cell including the same. The nanostructure 19 may be arranged such that individual elements thereof are close to each other. When the nanostructures 19 are arranged to be close each other, the nanostructure 19 has greater area contacting with the electron donor 7, and a path of the produced hole 15 to the nanostructure 19 may be shortened resulting in improvement of photoelectric conversion efficiency of the solar cell including the same.

The photoactive layer 11 may be formed in a thickness ranging from about 100 nm to about 500 nm in terms of improving photoelectric conversion efficiency.

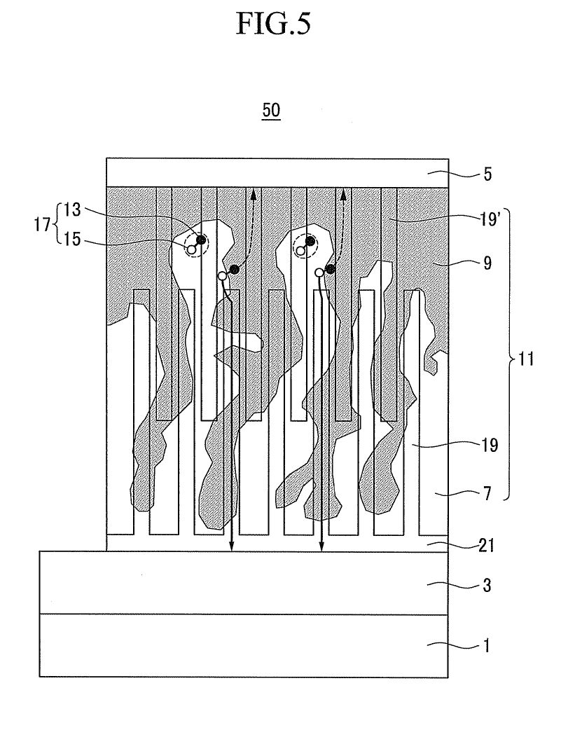

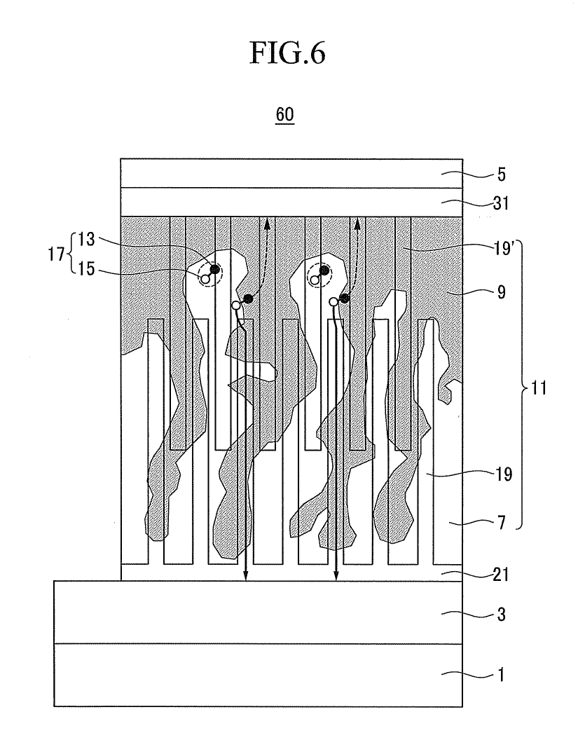

FIGS. 5 and 6 are cross-sectional views of another embodiments of organic solar cells 50 and 60. As shown in FIGS. 5 and 6, another embodiments of organic solar cells 50 and 60 further include a nanostructure 19′ which is connected to the cathode 5. The nanostructure 19′ functions as an electron transporter and may include an electron conductive material selected from the group consisting of a semiconductor element, a semiconductor compound, a semiconductor carbon material, a metallic carbon material which is surface-treated with a hole blocking material, a metal which is surface-treated with a hole blocking material and a combination thereof. Therefore, the movement speed of the electron 13 separated from the exciton 17 toward the cathode 5 may be increased. As a result, the electron 13 may be recombined with the hole 15 at a lower level, e.g., at the cathode 5, at a more rapid rate and therefore increase the amount of photocurrent available, improving photoelectric conversion efficiency. In addition, the nanostructure 19′ may scatter light, increasing the light path in the photoactive layer 11, resultantly improving photoelectric conversion efficiency.

As shown in FIG. 6, another embodiment of organic solar cell 60 further includes a hole blocking layer 31 between the cathode 5 and the photoactive layer 11.

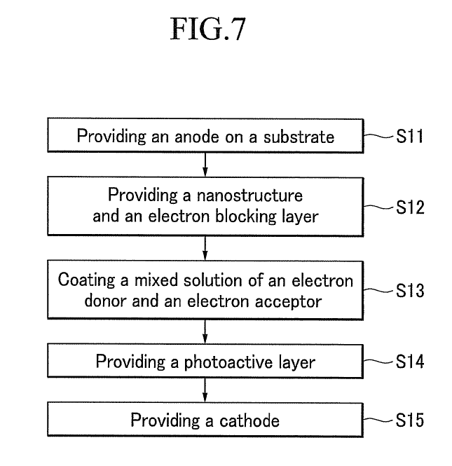

Hereinafter, referring to FIG. 7, a method of fabricating embodiments of the organic solar cells 10 and 20 having the aforementioned structure is illustrated.

First, an anode 3 is positioned on a substrate 1 (S11).

Then, the nanostructure 19 may be arranged in a direction substantially normal to the anode 3 by directly growing the nanostructure 19 on the anode 3 or etching a film (S12). Embodiments include configurations wherein the nanostructure 19 may be selectively etched or treated to make the surface hydrophilic.

In the embodiment wherein the nanostructure 19 is directly grown on the anode 3, an electron blocking layer 21 having substantially the same material as the nanostructure 19 is positioned between the anode 3 and photoactive layer 11. In the embodiment wherein the nanostructure 19 is formed on the anode 3 by etching a film, etch-rate and etch time may be controlled to form an electron blocking layer 21 having the same material as the nanostructure 19.

Then, a mixed solution prepared by dispersing an electron donor 7 and an electron acceptor 9 in a solvent is coated on the nanostructure 19 arranged on the anode 3 (S13). The coating method of the mixed solution prepared by dispersing an electron donor 7 and an electron acceptor 9 in a solvent may be selected from the group consisting of spray coating, dipping, reverse rolling, direct rolling, screen printing, spin coating, coating with a doctor blade, gravure coating, painting, slot die coating and various other similar methods depending on its viscosity, but the disclosure is not limited thereto. In accordance with the different kinds of materials used for forming the electron donor 7 and the electron acceptor 9, vacuum deposition may be used, for example copper phthalocyanine:C60 may be coated using co-deposition, but the coating method is not limited thereto.

Next, the solvent is removed after the mixture is coated on the nanostructures 19 to form a photoactive layer 11 (S14). Then, the cathode 5 is positioned on the photoactive layer 11, completing an organic solar cell 10 (S15). As discussed above, in another embodiment a hole blocking layer 31 may be further positioned on the photoactive layer 11 before providing the cathode 5 to prevent an electric short circuit, thus forming the organic solar cell 20.

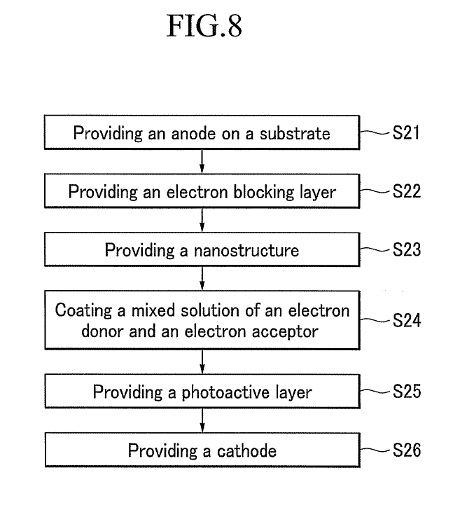

Hereinafter, referring to FIG. 8, a method of fabricating embodiments of the organic solar cells 30 and 40 having the aforementioned structure is illustrated.

First, an anode 3 is positioned on a substrate 1 (S21).

Then, a electron blocking layer 21 may be formed by coating the same material as the nanostructure 19 on the anode 3 (S22); e.g., a transition metal oxide such as MoO₃, V₂O₅, WO₃, and other materials with similar characteristics; a conductive polymer such as PEDOT:PSS, polyaniline, polypyrrole, poly(p-phenylene vinylene), MEH-PPV (poly[2-methoxy-5-(2′-ethyl-hexyloxy)-1,4-phenylene vinylene), MDMO-PPV (poly(2-methoxy-5-(3,7-dimethyloctyloxy)-1,4-phenylene vinylene), poly(3-alkylthiophene), polythiophene, and other materials with similar characteristics; pentacene; metal phthalocyanine such as copper phthalocyanine (CuPc), and other materials with similar characteristics; or a low molecular weight organic material such as TPD, and other materials having similar characteristics, once or several times. Embodiments include configurations wherein the coating may be performed by a general coating method.

Then, the nanostructure 19 may be arranged in a direction substantially normal to the electron blocking layer 21 by directly growing the nanostructure 19 on the anode 3 or etching a film (S23). Embodiments include configurations wherein the nanostructure 19 may be selectively etched or treated to make the surface hydrophilic.

Then, a mixed solution prepared by dispersing an electron donor 7 and an electron acceptor 9 in a solvent is coated on the nanostructure 19 arranged on the anode 3 (S24). The coating method of the mixed solution prepared by dispersing an electron donor 7 and an electron acceptor 9 in a solvent may be selected from the group consisting of spray coating, dipping, reverse rolling, direct rolling, screen printing, spin coating, coating with a doctor blade, gravure coating, painting, slot die coating and various other similar methods depending on its viscosity, but the disclosure is not limited thereto. In accordance with the different kinds of materials used for forming the electron donor 7 and the electron acceptor 9, vacuum deposition may be used, for example copper phthalocyanine:C60 may be coated using co-deposition, but the coating method is not limited thereto.

Next, the solvent is removed after the mixture is coated on the nanostructures 19 to form a photoactive layer 11 (S25). Then, the cathode 5 is positioned on the photoactive layer 11, completing an organic solar cell 30 (S26). As discussed above, in another embodiment a hole blocking layer 31 may be further positioned on the photoactive layer 11 before providing the cathode 5 to prevent an electric short circuit, thus forming the organic solar cell 40.

As described, since the nanostructure 19 and electron blocking layer 21 may be formed at the same time, and the photoactive layer 11 is formed by coating a mixture of an electron donor 7 and an electron acceptor 9, this method may contribute to simply fabricating organic solar cells with high efficiency and low cost.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. An organic solar cell comprising:
a cathode;
an anode disposed substantially opposite the cathode;
a photoactive layer disposed between the cathode and the anode; and
an electron blocking layer disposed between the anode and the photoactive layer,
wherein the photoactive layer comprises:
an electron donor;
an electron acceptor disposed adjacent to the electron donor; and
a nanostructure disposed adjacent to at least one of the electron donor and the electron acceptor,
wherein the nanostructure is connected to the anode, and comprises a hole transporting material selected from the group consisting of a semiconductor element, a semiconductor compound, a semiconductor carbon material, and a combination thereof, and
wherein the semiconductor element, the semiconductor compound, or the semiconductor carbon material satisfy the following Equation 1 and Equation 2:

|LUMO_{A}|>|CBE_{N}| [Equation 1]

|HOMO_{D}|>|VBE_{N}| [Equation 2]
wherein in Equation 1, LUMO_{A} refers to an energy level of a lowest unoccupied molecular orbital of the electron acceptor and CBE_{N} refers to a conduction band edge of the nanostructure, while in Equation 2, HOMO_{D} refers to an energy level of a highest occupied molecular orbital of the electron donor and VBE_{N} refers to a valance band edge of the nanostructure.

2. The organic solar cell of claim 1, wherein the semiconductor element comprises one selected from the group consisting of silicon, germanium and a combination thereof.

3. The organic solar cell of claim 1, wherein the semiconductor compound comprises one of a group II-VI compound, a group III-V compound, a group IV-VI compound, a group IV compound, a semiconductor metal oxide and a combination thereof.

4. The organic solar cell of claim 1, wherein the semiconductor carbon material is selected from the group consisting of carbon nanotube, graphene and a combination thereof.

5. The organic solar cell of claim 1, wherein the nanostructure has one of a substantially one-dimensional linear structure, a substantially two-dimensional flat structure and a three-dimensional cubic structure.

6. The organic solar cell of claim 1, wherein the nanostructure comprises one selected from the group consisting of nanotubes, nanorods, nanowires, nanotrees, nanotetrapods, nanodisks, nanoplates, nanoribbons and a combination thereof.

7. The organic solar cell of claim 1, wherein the nanostructure is treated to have one of a surface roughness and a hydrophilic surface.

8. The organic solar cell of claim 1, wherein the nanostructure is comprises about 0.1% to about 50% of an entire volume of the photoactive layer.

9. The organic solar cell of claim 1, further comprising a hole blocking layer disposed between the cathode and the photoactive layer.

10. An organic solar cell comprising:
a cathode;
an anode disposed substantially opposite the cathode;
a photoactive layer disposed between the cathode and the anode; and
an electron blocking layer disposed between the anode and the photoactive layer,
wherein the photoactive layer comprises:
an electron donor;
an electron acceptor disposed adjacent to the electron donor; and
a nanostructure disposed adjacent to at least one of the electron donor and the electron acceptor,
wherein some of the nanostructure is connected to the anode, and comprises a hole transporting material selected from the group consisting of a semiconductor element, a semiconductor compound, a semiconductor carbon material, and a combination thereof, wherein the semiconductor element, the semiconductor compound, or the semiconductor carbon material, which are included in the nanostructure connected to the anode, satisfy the following Equation 1 and Equation 2,

|LUMO_{A}|>|CBE_{N}| [Equation 1]

|HOMO_{D}|>|VBE_{N}| [Equation 2]
wherein in Equation 1, LUMO_{A} refers to an energy level of a lowest unoccupied molecular orbital of the electron acceptor and CBE_{N} refers to a conduction band edge of the nanostructure, while in Equation 2, HOMO_{D} refers to an energy level of a highest occupied molecular orbital of the electron donor and VBE_{N} refers to a valance band edge of the nanostructure, and
wherein the rest of the nanostructure is connected to the cathode, and comprises an electron conductive material selected from the group consisting of a semiconductor element, a semiconductor compound, a semiconductor carbon material, a metallic carbon material which is surface-treated with a hole blocking material, a metal which is surface-treated with a hole blocking material and a combination thereof.

11. A method of fabricating an organic solar cell, the method comprising:
providing an anode on a substrate,
providing a nanostructure on the anode such that the nanostructure is arranged substantially perpendicular to the anode, and at the same time providing an electron blocking layer on the anode;
coating a mixed solution of an electron donor and an electron acceptor on the nanostructure to form a photoactive layer, and
providing a cathode on the photoactive layer,
wherein the nanostructure comprises a hole transporting material selected from the group consisting of a semiconductor element, a semiconductor compound, a semiconductor carbon material and a combination thereof, and
wherein the semiconductor element, the semiconductor compound, and the semiconductor carbon material satisfy the following Equation 1 and Equation 2:

|LUMO_{A}|>|CBE_{N}| [Equation 1]

|HOMO_{D}|>|VBE_{N}| [Equation 2]
wherein in Equation 1, LUMO_{A} refers to an energy level of a lowest unoccupied molecular orbital of the electron acceptor and CBE_{N} refers to a conduction band edge of the nanostructure, while in Equation 2, HOMO_{D} refers to an energy level of a highest occupied molecular orbital of the electron donor and VBE_{N} refers to a valance band edge of the nanostructure.

12. The method of claim 11, further comprising:
providing a hole blocking layer between the cathode and the photoactive layer.

13. The method of claim 11, wherein the nanostructure is treated by at least one pretreatment process selected from the group consisting of selective etching to provide surface roughness and hydrophilic surface treatment.

14. A method of fabricating an organic solar cell, the method comprising:
providing an anode on a substrate,
providing an electron blocking layer on the anode,
providing a nanostructure on the electron blocking layer such that the nanostructure is arranged substantially perpendicular to the electron blocking layer,
coating a mixed solution of an electron donor and an electron acceptor on the nanostructure to form a photoactive layer, and
providing a cathode on the photoactive layer,
wherein the nanostructure comprises a hole transporting material selected from the group consisting of a semiconductor element, a semiconductor compound, a semiconductor carbon material and a combination thereof, and
wherein the semiconductor element, the semiconductor compound, and the semiconductor carbon material satisfy the following Equation 1 and Equation 2:

|LUMO_{A}|>|CBE_{N}| [Equation 1]

|HOMO_{D}|>|VBE_{N}| [Equation 2]
wherein in Equation 1, LUMO_{A} refers to an energy level of a lowest unoccupied molecular orbital of the electron acceptor and CBE_{N} refers to a conduction band edge of the nanostructure, while in Equation 2, HOMO_{D} refers to an energy level of a highest occupied molecular orbital of the electron donor and VBE_{N} refers to a valance band edge of the nanostructure.
